(19) United States
(12) Patent Application Publication
(10) Pub. No.: US 2021/0249663 A1
(43) Pub. Date: Aug. 12, 2021

(54) CARBON NANOTUBE (CNT)-METAL COMPOSITE PRODUCTS AND METHODS OF PRODUCTION THEREOF

(71) Applicant: TORTECH NANO FIBERS LTD, MAALOT TARSHISHA (IL)

(72) Inventors: Liron Issman, Kiryat Motzkin (IL); Meir Hefetz, Mitzpe Harashim (IL); Stanislav Kozachkevich, Kibutz Dan (IL); Arieh Meitav, Rishon Le-Cion (IL); Ivan Surzhyk, Netanya (IL); Mor Albert, Petach-Tikva (IL)

(21) Appl. No.: 16/972,613

(22) PCT Filed: Jun. 11, 2019
(86) PCT No.: PCT/IL2019/050661

§ 371 Date: Dec. 7, 2020

Related U.S. Application Data
(60) Provisional application No. 62/684,200, filed on Jun. 13, 2018.

(51) Int. Cl. H01M 4/66; H01M 4/82; H01M 4/80

(52) U.S. Cl. CPC H01M 4/667; H01M 4/80; H01M 4/82

(57) ABSTRACT

The present invention provides carbon-nanotube (CNT)-polymer-metal composite substrate products, each product including a first current collector including at least one carbon nanotube (CNT) mat and a high conducting metallic element in electrical connection with a first tab, the high conducting metallic element bound to the at least one carbon nanotube mat, and optionally including a second current collector including a metallic conducting element in electrical connection with a second tab, a separator material separating between the first and second current collectors, an electrolyte solution disposed between the first collector and the second collector and a housing configured to house the first collector, second collector, separator material electrolyte solution and active material.

### FIELD OF THE INVENTION

The present invention relates generally to carbon nanotube-metal composite products and methods of production thereof, and more specifically to methods and apparatus for efficient current collection using CNT-metal composite substrates.

### BACKGROUND OF THE INVENTION

Many designs of power apparatus are inefficient, both with respect to the weight of the electrodes, and with respect to the energy provision per unit weight.

An effort has been made to improve the design of power sources, such as batteries, capacitors and fuel cells and non-energy storage devices, such as electrochemical synthesis cells, electronic shielding units, heating elements and lightning rods. However, many commercially available systems remain inefficient.

There therefore remains an unmet need for improved-efficiency power sources and non-energy storage devices.

### SUMMARY OF THE INVENTION

It is an object of the present invention to provide improved carbon nanotube (CNT)-metal composite substrates.

In some further embodiments of the present invention, improved products comprising CNT-metal composite substrates are provided.

In some further embodiments of the present invention, reduced-weight products comprising CNT-metal composite substrates are provided.

In some additional embodiments of the present invention, improved products comprising CNT-metal composite substrates for current collection are provided.

In some further additional embodiments of the present invention, improved products are provided comprising a composite material of light-weight, conductive, thin substrate with a relatively high tensile strength.

In some additional embodiments of the present invention, reduced-weight products comprising CNT-metal composite substrates for current collection are provided.

In some additional embodiments of the present invention, improved methods for producing products comprising CNT-metal composite substrates are provided.

In some additional embodiments of the present invention, improved methods for producing products comprising CNT metal composite substrates for current collection are provided.

It is an object of some aspects of the present invention to provide methods and apparatus with efficient current collection.

In some embodiments of the present invention, improved methods and apparatus are provided for reduced-weight, efficient current collection.

In other embodiments of the present invention, a method and system is described for providing high-efficiency current collection.

In additional embodiments for the present invention, a method and apparatus is provided for low-weight, high-efficiency current collection.

The present invention provides apparatus and methods for providing power, the apparatus including a first current collector including at least one carbon nanotube (CNT) mat and a high conducting metallic element in electrical connection with a first tab, the high conducting metallic element bound to the at least one carbon nanotube mat, a second current collector including a metallic conducting element in electrical connection with a second tab, a separator material separating between the first and second current collectors, an electrolyte solution disposed between the first collector and the second collector and a housing configured to house the first collector, second collector, separator material and electrolyte solution.

The present invention further provides carbon-nanotube (CNT) metal composite substrate products, each product including a first current collector including at least one carbon nanotube (CNT) mat, a first active material and a high conducting metallic element in electrical connection with a first tab, the high conducting metallic element bound to the at least one carbon nanotube mat, and optionally including a second current collector including a metallic conducting element in electrical connection with a second tab, a separator material separating between the first and second current collectors, an electrolyte solution disposed between the first collector and the second collector and a housing configured to house the first collector, second collector, separator material electrolyte solution and active material.

According to some embodiments of the present invention, the apparatus is a non-energy storage device selected from the group consisting of an electrochemical synthesis cell, an electronic shielding unit, an EMI (electromagnetic interference) device or apparatus, a heating element and a lightning rod.

According to some additional embodiments of the present invention, CNT-metal products of the present invention are used as termination elements to electrically connect a device to an external electrical element.

According to some further embodiments of the present invention, CNT-metal products of the present invention may be used for many practical applications. One non-limiting example is for CNT-metal joining techniques such as: brazing, welding, soldering and other connecting methods.

There is thus provided according to an embodiment of the present invention, an apparatus for providing power, the apparatus including;
a. a first current collector having a resistivity in a range between 1-20 mohm/sq, the first current collector including;
   i. at least one carbon nanotube (CNT) mat; and
   ii. a high conducting metallic element comprising at least a first metal in electrical connection with a first tab, the high conducting metallic element bound to the at least one carbon nanotube mat;
b. a second current collector including a metallic conducting element comprising a second metal in electrical connection with a second tab;
c. a separator material separating between the first and second current collectors;
d. an electrolyte solution disposed between the first collector and the second collector; and
e. a housing configured to house the first collector, the second collector, the separator material and the electrolyte solution.

There is thus provided according to another embodiment of the present invention, an apparatus for providing power, the apparatus including;
a. a first current collector having a resistivity in a range between 1-20 mohm/sq, the first current collector including;
   i. at least one carbon nanotube (CNT) mat;
   ii. a high conducting metallic element comprising at least a first metal of a density of at least 4 g/cm³ in electrical connection with a first tab, the high conducting metallic element bound to the at least one carbon nanotube mat; and
   iii. a first active material;
b. a second current collector including a metallic conducting element comprising a second metal in electrical connection with a second tab and a second active material;
c. a separator material separating between the first and second current collectors;
d. an electrolyte solution disposed between the first collector and the second collector; and
e. a housing configured to house the first collector, second collector, separator material and electrolyte solution.

There is thus provided according to an embodiment of the present invention, an apparatus for providing power, the apparatus including;
a. a first current collector having a resistivity in a range between 1-20 mohm/sq, the first current collector including;
   i. at least one carbon nanotube (CNT) mat; and
   ii. a high conducting metallic element comprising at least a first metal of a density of more than 4 g/cm³ in electrical connection with a first tab, the high conducting metallic element bound to the at least one carbon nanotube mat;
b. a second current collector including a metallic conducting element comprising at least a second metal of a density of less than 4 g/cm³ in electrical connection with a second tab;
c. a separator material separating between the first and second current collectors;
d. an electrolyte solution disposed between the first collector and the second collector; and
e. a housing configured to house the first collector, second collector, separator material and electrolyte solution.

Additionally, according to an embodiment of the present invention, the first current collector is of a mean weight per area in a range of 1 to 4 mg/cm².

Moreover, according to an embodiment of the present invention, the high conducting metallic element includes copper. Additionally or alternatively, it may include nickel. In other devices and other battery types than LIB, the anode may be of other metals.

Furthermore, according to an embodiment of the present invention, the copper is in the form of a perforated foil.

Further, according to an embodiment of the present invention, the at least one carbon nanotube (CNT) mat includes two carbon nanotube (CNT) mats.

Yet further, according to an embodiment of the present invention the high conducting metallic element is sandwiched between the two carbon nanotube (CNT) mats or joined with just one CNT mat.

Additionally, according to an embodiment of the present invention, the apparatus further includes an active material coated/applied on the at least one mat.

Moreover, according to an embodiment of the present invention, the apparatus is a power source selected from a battery, a capacitor and a fuel cell.

According to some embodiments of the present invention, the battery is a lithium ion battery.

Further, according to an embodiment of the present invention, the second current collector includes at least one of aluminum, graphite, silicon, a phosphate, lithium, an oxide and combinations thereof.

Additionally, according to an embodiment of the present invention, the apparatus is configured to provide energy per unit weight of around 50 Wh/kg to 150 Wh/kg or up to 800 Wh/kg.

Furthermore, according to an embodiment of the present invention, the apparatus is configured to provide power per unit weight of around 200 W/kg to 5 kW/kg.

There is thus provided according to another embodiment of the present invention, an apparatus for providing power, the apparatus including;
a. a first current collector having a resistivity in a range between 1-20 mohm/sq, the first current collector including;
   i. at least one carbon nanotube (CNT) mat or substrate; and
   ii. a high conducting metallic element comprising at least a first metal of a density of more than 4 g/cm³ in electrical connection with a first tab, the high conducting metallic element bound to the at least one carbon nanotube mat;
b. a second current collector having a resistivity in a range between 1-20 mohm/sq, the first current collector including;
   i. at least one carbon nanotube (CNT) mat or substrate; and
   ii. a high conducting metallic element comprising at least a second metal of a density of up to 4 g/cm³ in electrical connection with a first tab, the high conducting metallic element bound to the at least one carbon nanotube mat;
c. a separator material separating between the first and second current collectors;
d. an electrolyte solution disposed between the first collector and the second collector; and
e. a housing configured to house the first collector, second collector, separator material and electrolyte solution.

There is thus provided according to another embodiment of the present invention, a method for manufacturing an apparatus for providing at least one of power and energy, the method including;
a. forming a first current collector having a resistivity in a range between 1-20 mohm/sq, including;
   1. binding at least one carbon nanotube (CNT) mat with a high conducting metallic element in electrical connection with a first tab;
   2. coating/applying the at least one carbon nanotube (CNT) mat with an active material;
b. preparing a second current collector a metallic conducting element in electrical connection with a second tab and coating the second current collector with an active material;
c. disposing a separator material between the first current collector and the second current collector;
d. introducing the first current collector the second current collector and the separator material into a housing; and
e. adding an electrolyte solution in between the first collector and the second collector thereby forming the apparatus.

Additionally, according to an embodiment of the present invention the forming step is selected from a sandwich approach and a physical vapor deposition (PVD) approach.

Additionally, according to an embodiment of the present invention the binding step includes methods such as, but not limited to, physical methods, chemical methods, gluing, electrical methods, non-electrical methods.

Moreover, according to an embodiment of the present invention, the apparatus is a non-energy storage device selected from the group consisting of an electrochemical synthesis cell, an electronic shielding unit, a heating element and a lightning rod.

Importantly, according to an embodiment of the present invention, the method further includes treating the at least one carbon nanotube (CNT) mat to reduce at least one of a porosity or a wetting, or to increase an oleophobicity (oil-repelling) thereof.

Additionally, according to an embodiment of the present invention, the method further includes treating the at least one carbon nanotube (CNT) mat with polymer impregnation to reduce porosity thereof.

Additionally, according to an embodiment of the present invention, the method further includes treating the at least one carbon nanotube (CNT) mat with polymer impregnation to improve physical properties thereof.

Additionally, according to an embodiment of the present invention, the method further includes treating the at least one carbon nanotube (CNT) mat with polymer impregnation to electrically insulate the carbon nanotube mat.

Additionally, according to an embodiment of the present invention, the treating step includes heating in air the at least one carbon nanotube (CNT) mat or substrate to a temperature above 300° C. for at least 30 minutes, or at least 400° C. in air or any other suitable oxidizing environment.

Furthermore, according to an embodiment of the present invention, the heating in air step includes the at least one carbon nanotube (CNT) mat to a temperature of around 450° C. for around one hour.

Yet further, according to an embodiment of the present invention, the high conducting metallic element is disposed between two carbon nanotube (CNT) mats.

Further, according to an embodiment of the present invention, there is provided an electromagnetic interference (EMI) shielding device including at least one current collector and at least one conducting metallic element.

The present invention will be more fully understood from the following detailed description of the preferred embodiments thereof, taken together with the drawings.

### BRIEF DESCRIPTION OF THE DRAWINGS

The invention will now be described in connection with certain preferred embodiments with reference to the following illustrative figures so that it may be more fully understood.

With specific reference now to the figures in detail, it is stressed that the particulars shown are by way of example and for purposes of illustrative discussion of the preferred embodiments of the present invention only and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the drawings:

FIG. 1A is a simplified diagram of a typical weight distribution of components of a prior art energy cell;

FIG. 1B is a simplified diagram of a typical weight distribution of components of a prior art power cell;

FIG. 2A is a simplified flow chart of the main steps in a method of preparing a carbon nanotube-copper composite sandwich current collector of FIG. 5A, in accordance with an embodiment of the present invention;

FIG. 2B is a simplified flow chart of the main steps in a method of preparing a carbon nanotube-copper PVD-coated current collector of FIG. 5B, in accordance with an embodiment of the present invention;

FIG. 3A is a simplified schematic diagram of an electrode, in accordance with an embodiment of the present invention;

FIG. 3B is an image of a carbon-nanotube (CNT) mat, in accordance with an embodiment of the present invention;

FIGS. 4A-4D are simplified schematic diagrams of carbon nanotubes (CNT) mats—(a) CNT mat (pristine); (b) CNT mat with 3D polymer impregnation; (c) CNT mat with skin, impregnated with polymer; and (d) CNT mat with skin, in accordance with some embodiments of the present invention;

FIGS. 5A and 5B are simplified schematic illustrations of two methods for producing a current collector, in accordance with embodiments of the present invention;

FIG. 6A shows an image of a perforated thin copper foil of a current collector, in accordance with an embodiment of the present invention;

FIG. 6B shows a strip of CNT mat, bonded to perforated copper foil of an electrode, in accordance with an embodiment of the present invention;

FIG. 6C shows a strip of FIG. 7, coated with a negative active material of an electrode, in accordance with an embodiment of the present invention;

FIG. 7 shows a number of anodes each with a tab, which has been cut from the strip of FIG. 6B, in accordance with an embodiment of the present invention;

FIG. 8 shows a PVD-copper-coated CNT mat of an electrode, in accordance with an embodiment of the present invention;

FIG. 9 shows a graph of formation capacity of a CNT-impregnated with polymer current collector in comparison with, pristine CNT and Cu foil based current collectors, in accordance with an embodiment of the present invention;

FIG. 10A is a simplified schematic of a device with at least one CNT element that is ultrasonically welded along one side of the electrode to a copper foil termination hold, in accordance with an embodiment of the present invention;

FIG. 10B is a simplified diagram of a device with at least one CNT element that is ultrasonically welded to a copper foil termination leg, in accordance with an embodiment of the present invention; and

FIG. 11 is a simplified graph of a comparison of attenuation of the electromagnetic field as a function of electromagnetic frequency of an EMI shielding device of the present invention compared with that of standard prior art devices, in accordance with an embodiment of the present invention.

In all the figures similar reference numerals identify similar parts.

### DETAILED DESCRIPTION OF THE EMBODIMENTS

In the detailed description, numerous specific details are set forth in order to provide a thorough understanding of the invention. However, it will be understood by those skilled in the art that these are specific embodiments and that the present invention may be practiced also in different ways that embody the characterizing features of the invention as described and claimed herein.

In some further embodiments of the present invention, improved products comprising CNT-based substrates are provided.

In some further embodiments of the present invention, reduced-weight products comprising CNT-based substrates are provided.

In some additional embodiments of the present invention, improved products comprising CNT-based substrates for current collection are provided.

In some additional embodiments of the present invention, reduced-weight products comprising CNT-based substrates for current collection are provided.

In some additional embodiments of the present invention, improved methods for producing products comprising CNT-based substrates are provided.

The present invention discloses a novel current collector based on a CNT (carbon nanotube) mat that is applicable in power sources such as batteries, capacitors and fuel cells and also in non-energy storage devices such as electrochemical synthesis cells, electronic shielding units, heating elements and lightning rods. For example in battery systems the novel current collector offers weight and cost savings compared with a conventional system, noting that weight saving directly improves energy per unit weight.

The invention is described referring to a primary and/or rechargeable lithium-ion battery (LIB or LB) although no limitation is intended and it can be applicable to other battery/electrode types or any of the devices referred to above. A typical lithium-ion cell comprises a lithium negative (anode) and usually an oxide or phosphate positive (cathode). The negative electrode (anode) consists of a graphite, silicon or other intercalation based lithium active material, or alternatively metallic lithium, supported on a copper current collector, usually a foil or mesh. The positive electrode (cathode) consists usually of oxide or phosphate based active material supported on an aluminum current collector.

By active material is meant a material deposited on a current collector which provides chemical energy and discharge (the other materials are inert).

For an anode, the active material may be lithium, graphite, Si or any other anodic material. The cathode active material may be a metal oxide or phosphate.

The negative and positive electrodes are wrapped with separator material, wound or layered into a jelly roll or stack and inserted for example into cylindrical, prismatic or pouch type containers. Usually the electrodes are tabbed to provide external contacts, electrolyte is added to the cell and electrochemical formation is performed. The cell is then sealed.

Cells are optimized for energy or power and the current draw capability of the current collector is of prime importance. For electric vehicle/hybrid applications using for example lithium-iron phosphate chemistry, energy cells will have high energy per unit weight of around 150 Wh/kg and power per unit weight of only 200 W/kg.

In contrast, power cells with same chemistry of this type will have power levels reaching up to 5 kW/kg but energy per unit weight of only 50 Wh/kg. Practically, for energy cells of this type, the active material tends to be a thick layer on the foil supporting it, while in power cells the active material is a thin layer on the foil supporting it. In the figures below a weight breakdown for energy and power cells is provided.

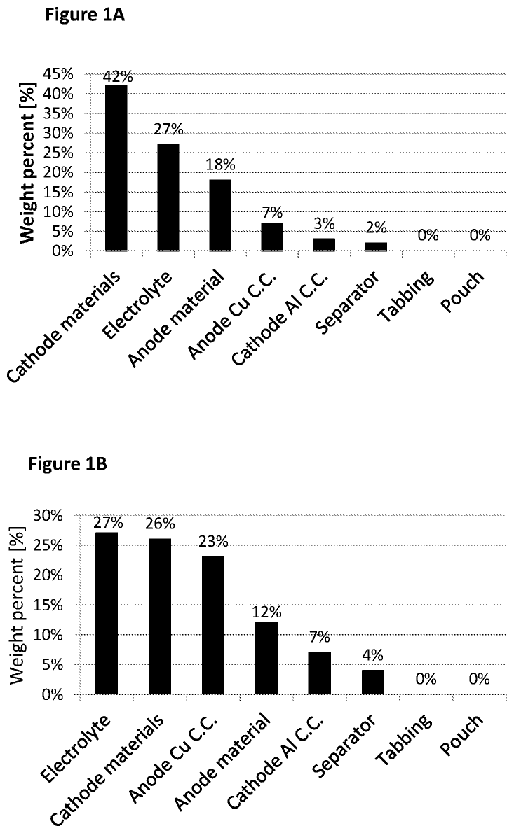

Reference is now made to FIG. 1A, which is diagram of a typical weight distribution of components of a prior art energy cell. It can be seen that in the energy cell the copper (anode) current collector comprises only 7% of the cell weight, which is an acceptable figure.

Turning to FIG. 1B, there is seen diagram of a typical weight distribution of components of a prior art power cell. As can be seen, the copper current collector (anode) weighs up to 23% of the cell weight, which is an excessively high figure, which also impacts on the cost of product. A copper current collector thickness of 8-20 microns is typical in the prior art.

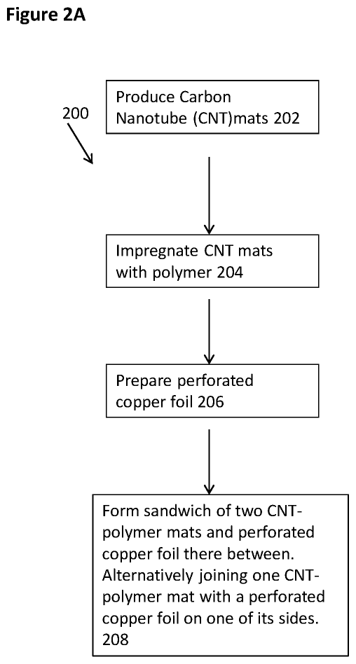

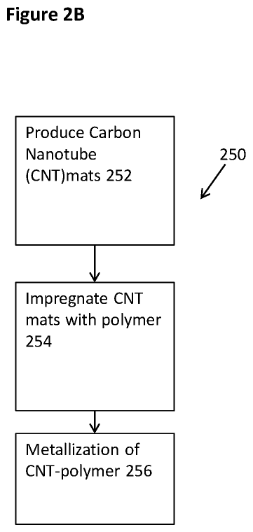

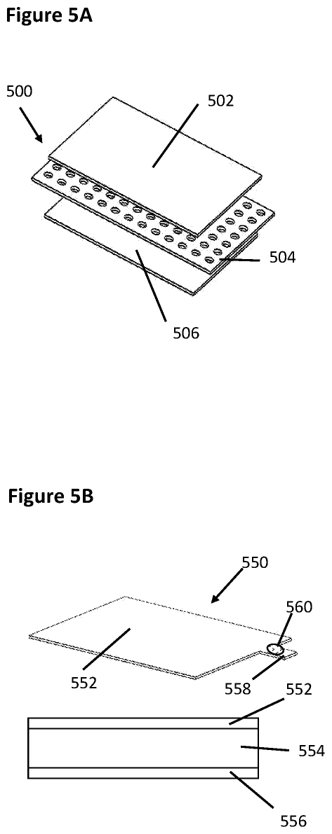

FIG. 2A is a simplified flow chart 200 of the main steps in a method of preparing a carbon nanotube-copper composite sandwich current collector of FIG. 5A, in accordance with an embodiment of the present invention.

In a producing a carbon-nanotube (CNT) mat or mats step 202, several gaseous components are injected into a reactor. The reactor is inside a furnace in a temperature range of 900-1200 Celsius. The pressure range in the ceramic tube reactor is between 0.5-1 bar gauge. The gaseous components include a carbon source, which is gaseous under the above conditions, such as, but not limited to, a gas, such as methane, ethane, propane, butane, saturated and unsaturated hydrocarbons and combinations thereof. Another gaseous component is a catalyst or catalyst precursor, such as, ferrocene. A carrier gas is typically used, such as, helium, hydrogen, nitrogen and combinations thereof. In some cases, this process is defined as a floating catalyst CVD (chemical vapor deposition) process.

Without being bound to any particular theory, the catalyst reduces the activation energy in extracting carbon atoms from the gas and carbon nanotubes start to nucleate on top of the catalyst, which may be in the form of nano-particles. Further into the tubular reactor, the CNT are elongated and this continues, until a critical mass is formed in the form of an aero-gel-like substance, which exits in the reactor. The aero-gel-like substance is collected on a rotating drum, which moves from side to side. The speed of rotation of the rotating drum and other process conditions and duration determine the final thickness and properties of the carbon-nanotube mat. A typical range of thickness of the CNT mat is 10-150 microns.

In an impregnating CNT mat with polymer step 204, at least one thermoplastic organic polymer is used. Some non-limiting examples of these polymers are sodium carboxymethyl cellulose (NaCMC), polyvinylidenefluoride (PVDF), PVA, PVP and combinations thereof.

The impregnating step may be performed by one or more processes known in the art, such as, but not limited to polymer deposition, polymer dip-coating, polymerization on the CNT mat, polymer formation or any other method known in the art. The impregnation step typically deposits another 1-50 microns, 3-30 microns, or 4-15 microns of polymer. The polymer enhances the tensile strength of the CNT (see Table 4 below).

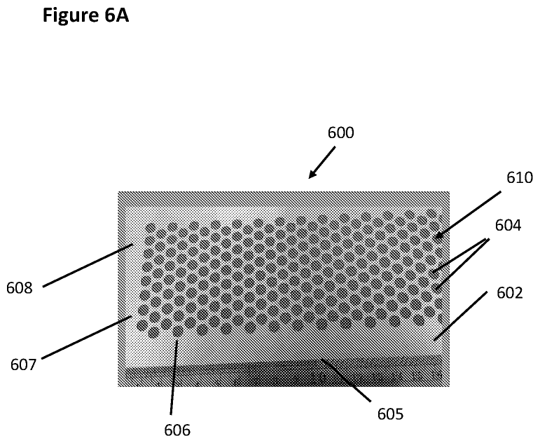

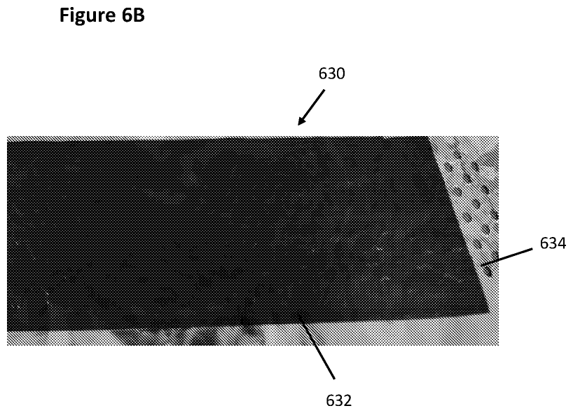

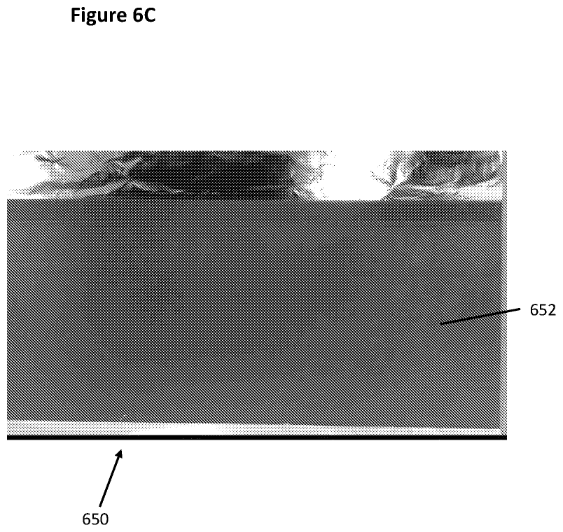

In a preparing perforated copper foil step 206, a copper foil of a thickness in a range of from 5-30 microns, 6-25 microns or 8-20 microns is obtained. The perforations are typically circular. The perforations may be formed by any one or more methods known in the art, such as, but not limited to punching, laser cutting, chemical or physical etching and the like. The percent of area removed is typically between 10-90%, 20-80%, 30-70%, or 40-60%. The perforations may be of other shapes and forms, such as rectangular, square, triangular, irregular and combinations thereof. In some cases, one or more borders of the perforated copper foil are left without perforations, sometimes for the purpose of tabbing, see FIG. 6A.

In a forming a sandwich of two CNT-polymer mats and perforated copper foil there-between step 208, the perforated copper foil is placed between two CNT-polymer mats, with the borders/margin (606, 608, FIG. 6A) of the copper foil left protruding beyond the cover of the CNT-polymer mats (FIG. 5A). These layers may be pressed, joined, glued together by any suitable means, known in the art.

Reference is now made to FIG. 2B, which is a simplified flow chart 250 of the main steps in a method of preparing a carbon nanotube-copper PVD-coated current collector of FIG. 5B, in accordance with an embodiment of the present invention;

In a producing a carbon-nanotube (CNT) mat or mats step 252, several gaseous components are injected into a reactor. The reactor is inside a furnace in a temperature range of 900-1200 Celsius. The pressure range in the ceramic tube reactor is between 0.5-1 bar gauge. The gaseous components include a carbon source, which is gaseous under the above conditions, such as, but not limited to, a gas, such as methane, ethane, propane, butane, saturated and unsaturated hydrocarbons and combinations thereof. Another gaseous component is a catalyst or catalyst precursor, such as, ferrocene. A carrier gas is typically used, such as, helium, hydrogen, nitrogen and combinations thereof. In some cases, this process is defined as a floating catalyst CVD (chemical vapor deposition) process.

Without being bound to any particular theory, the catalyst reduces the activation energy in extracting carbon atoms from the gas and carbon nanotubes start to nucleate on top of the catalyst, which may be in the form of nano-particles. Further into the tubular reactor, the CNT are elongated and this continues, until a critical mass is formed in the form of an aero-gel-like substance, which exits the reactor. The aero-gel-like substance is collected on a rotating drum, which moves from side to side. The speed of rotation of the rotating drum and other process conditions and duration determine the final thickness and properties of the carbon-nanotube mat. A typical range of thickness of the CNT mat is 10-150 microns.

In an impregnating CNT mat with polymer step 254, at least one thermoplastic organic polymer is used. Some non-limiting examples of these polymers are sodium carboxymethyl cellulose (NaCMC), polyvinylidenefluoride (PVDF), PVA, PVP and combinations thereof.

The impregnating step may be performed by one or more processes known in the art, such as, but not limited to polymer deposition, polymer deep-coating, polymerization on the CNT mat, polymer formation or any other method known in the art. The impregnation step typically deposits another 1-50 microns, 3-30 microns, or 4-15 microns of polymer. The polymer enhances the tensile strength of the CNT (see Table 4 below).

In a metallization of CNT-polymer mat step 256, the CNT mat receives copper deposition on both sides or on one side, by any one or more suitable methods known in the art, such as PVD, CVD, electrolytic coating, electroless coating and the like, and combinations thereof. The thickness of the copper deposited is typically in the range of 10 nm-50 microns, 30 nm-30 microns, 40 nm-15 microns, or 100 nm-10 microns.

According to some embodiments of the present invention a polymer is impregnated into a CNT mat to reduce or eliminate a parasitic reaction between an electrolyte and the high surface area of CNT fibers.

Polymer application to CNT prior to metal coating/application:
1. The application of polymer can be performed in several ways which include impregnation, step polymerization, dip coating, lay-up and many more. The goal of these application techniques is to make an electrical insulation between the CNT mat and the coated metal, to reduce parasitic reactions during battery function which include for example electrolyte reduction.

The following development step may be conducted by two approaches:

(a) Impregnation of polymer into the 3D CNT mat (prior to metallization) thereby eliminating the electrolyte penetration and contact with the CNT

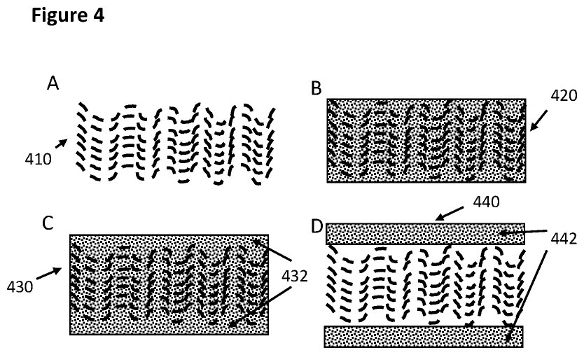

(b) Forming “perfect” polymeric “skin” on the CNT external surface. This skin should eliminate any electric contact between the metallic layer deposited on the skin and the CNT. In this case the electrolyte will penetrate into the CNT mat, however since the CNT is electrically insulated there will be no reduction process of the electrolyte on the CNTs. Both of these methods are schematically illustrated in FIG. 4A-4D.

It should be understood that these flowcharts and figures are exemplary and should not be deemed limiting. Some of the sequences of the steps may be changed. Some steps may not be performed. Some or all of flowcharts 2A and 2B may be combined in various combinations and permutations.

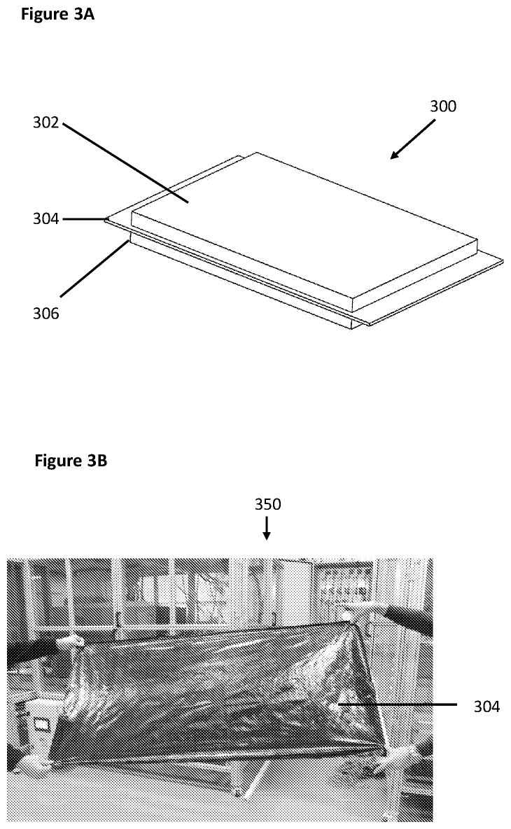

Reference is now made to FIG. 3A, which is a simplified schematic diagram of an electrode 300, in accordance with an embodiment of the present invention.

The inventors have found that a CNT woven or non-woven mat fiber agglomerate 302, the subject of U.S. Pat. No. 7,323,157, provides the basis for the improved negative current collector (anode) 300. This CNT mat is robust and freestanding, comprising an agglomerate of interlocking thin CNT fibers of diameter 5-7 nm and length typically at least hundreds of microns long, produced in a high temperature continuous web process without binder materials. Lack of binder materials is important to ensure purity and electrochemical stability. Mat thickness is typically 10-20 microns, density is 5-10 gr/m² and porosity 75%. Thickness and porosity are adjustable as per process conditions.

A sandwich of two CNT mats 302, 306 is provided with an electrode substrate current collector 304 disposed there-between.

FIG. 3B is an image 350 of a carbon-nanotube (CNT) mat 304, in accordance with an embodiment of the present invention.

Experimentation, based on building and testing current voltage characteristics of cells, however, has shown that the CNT mat current collector alone, if used to support the negative active material, has a too high electrical resistance to compete with the standard copper foil current collector as regards current withdrawal capabilities. It should be noted that for some applications, such as very long duration discharge cells (at a low rate cells) or electronic shielding, a CNT mat alone may suffice (with a high resistivity value).

There are also technical problems of tabbing to the mat since normal, convenient techniques such as spot welding or ultrasonic welding to a metal contact do not work with the CNT alone.

Reference is now made to FIGS. 4A-4D, which are simplified schematic diagrams of carbon nanotubes (CNT) mats—(a) CNT mat (pristine) 410, without polymer; (b) CNT mat with three-dimensional (3D) polymer impregnation (without skin), 420; (c) CNT mat 430 with skin(s) 432, and impregnated with 3D polymer, and (d) CNT mat 440 only with polymer skin 442, in accordance with some embodiments of the present invention.

Impregnation of polymer into CNT forms CNT-polymer composite, enabling easier dealing with the CNT mat and increase the tensile strength of the CNT C.C. Following the impregnation, Cu thin coating is applied on the CNT-Composite. The coating may be applied via PVD, electroless coating or via electrolytic copper deposition. Another option is to make a CNT-perforated Cu foil—CNT sandwich.

The process conditions and raw materials determine which of products shown in FIGS. 4B-4D will be obtained. Increasing the molecular weight and/or changing other properties of the polymer will prevent, in some case, it entering the CNT mat, due to physical/chemical restriction, leading to the formation of a CNT mat with a polymer skin (FIG. 4D) without the polymer penetrating the CNT mat in a 3D form.

Table 1 shows a simplified comparison of prior art energy and power cells compared with the energy cells and power cells of the present invention. In the present invention, the prior art copper electrode (anode) is replaced with a carbon-nanotube-copper electrode.

TABLE 1
Comparison of prior art energy and power cells (copper current
collectors Copper C.C.) with the cells of the present invention
with carbon-nanotube current collectors (CNT-C.C.)

| | | B | Increase of |
|---|---|---|---|
| | A | Present | Specific Energy |
| | Copper C.C. | invention | by replacing Cu- |
| | Weight* % | CNT-C.C. | C.C. (A) with |
| | (prior art) | Weight* % | CNT - C.C. (B) |
| LIB Energy cell | 6%-10% | 1%-2% | 5%-10% |
| LIB Power cell | 15%-30% | 5%-10% | 10%-30% |

*Weight including all cell elements, excluding cell enclosure case/pouch

The present invention provides an improved cost-effective current collector, with weight saving characteristics, which substitutes the conventional prior-art negative (copper) current collector. While cost effectiveness might be questionable, the gain due to weight reduction is obvious.

According to some embodiments of the present invention, the electrodes of the present invention provide current draw characteristics which are maintained relative to the prior art versions, coupled with a substantial raise and improvement of energy output per unit weight. This is particularly with respect to power cells.

The issue is less relevant for positive electrodes since the current collector used is of lightweight aluminum (density only 2.7 gm/cc, difficult to suggest alternative materials), compared with copper (density 8.9 gm/cc). Still same principle may be applied via perforated Al foil or Aluminum-PVD.

Reference is now made to FIGS. 5A and 5B, which is are simplified schematic illustration of two respective methods 500, 550 for producing a current collector, in accordance with embodiments of the present invention.

The inventors have overcome the aforementioned limitations using two main strategies.

In the first approach (sandwich approach method, 500) the current collector is built from a composite of two CNT mats 502, 506 sandwiching and bonded to a thin (8-20 micron) and perforated copper foil 504. Copper foil is rigid and cost effective compared to other supports such as woven or expanded copper mesh. The edges of the foil are left unperforated and free of CNT mat and active material in order to provide tabbing areas. The CNT mat is bonded by a method selected from physical, chemical, electric, non-electric methods and combinations thereof to join together the CNT with the metal.

In accordance with embodiments of the present invention, the CNT mats are joined with the copper foil by first, etching the copper foil with an acid and second, attached together by contacting using (isopropyl alcohol) IPA, or other liquid/s enhancing Van-der Waals forces between the CNT and the foil on the copper and CNT to make a physical connection between them) either on both sides of the perforated copper foil, or just on one side. Onto this support, the active material is coated by slurry application on both sides. If there is only one CNT mat used for the current collector, the active material loading on each side should be adjusted to ensure adequate capacity balance on both sides of the electrode.

In the second approach (PVD approach method, 550), a CNT mat 554 is coated on both sides with a thin (typically 0.1-1 microns) layer of copper 552, 556 using PVD (physical vapor deposition). Coating with active material is performed as usual and tabbing is simply made by any suitable welding method such as, but not limited to any suitable connecting method known in the art, such as ultrasonic welding, laser welding and others. In one example, ultrasonic welding of a tab contact 558 with a weld 560 is performed directly to the PVD copper layer.

The PVD approach may include any suitable form of metallization of the CNT mat, known in the art. The processing may be varied, thus for some cell types only one side of the CNT mat may carry copper. Similarly instead of deposition of copper via PVD, electroplating or electroless plating, magneton sputtering, electron beam coating, seeding, physical deposition or chemical deposition by for example thermal reduction processing, may be used. For other battery types or device types, other metals than copper, for example nickel, may be deposited on the CNT mat. The two approaches are shown schematically in FIG. 5.

Turning to FIG. 6A, there is seen an image of a perforated thin copper foil 602 of an electrode 600, comprising numerous perforations 604, in accordance with an embodiment of the present invention. The perforated thin copper foil (8-20 microns thick), is, for example used in the sandwich approach of FIG. 5. Various perforation designs (for instance varying the shape and % coverage of perforations may be used so as to reduce the net foil weight while optimizing conductivity) are possible.

It should be noted that in FIG. 6, on each side 605, 607 of a perforated area 610 is provided with a corresponding unperforated margin 606, 608 to allow for tabbing. Typically the CNT mat(s) 502, 506 and active material are located just to cover the perforated areas.

FIG. 6B shows an image comprising a strip of CNT mat 632, bonded to perforated copper foil 634 of an electrode 630, in accordance with an embodiment of the present invention.

FIG. 6C shows the strip of FIG. 6B, coated with a negative active material 652 such as, but not limited to graphite, of an electrode 650, in accordance with an embodiment of the present invention.

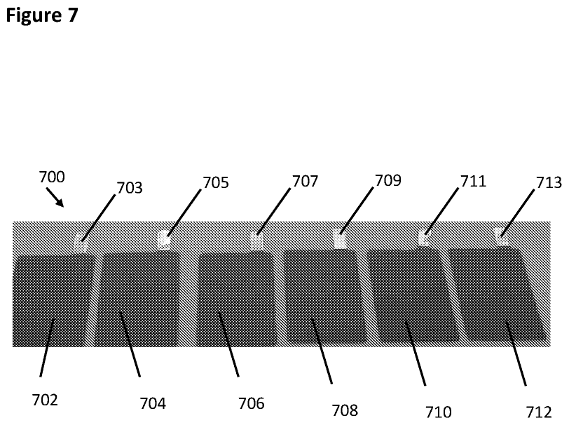

FIG. 7 shows an image 700 of a number of anodes 702, 704, 706, 708, 710 and 712 each with a corresponding tab 703, 705, 707, 709, 711 and 713, which have been cut from the strip in FIG. 6C.

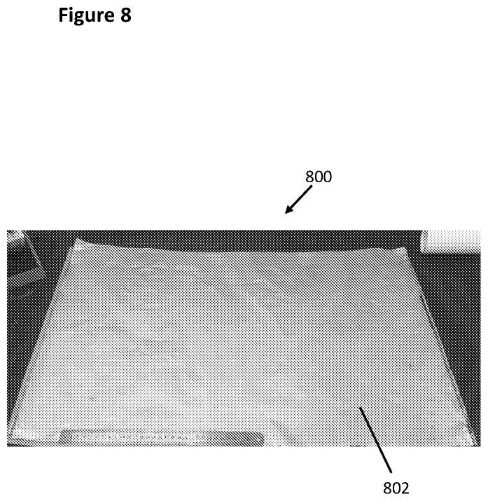

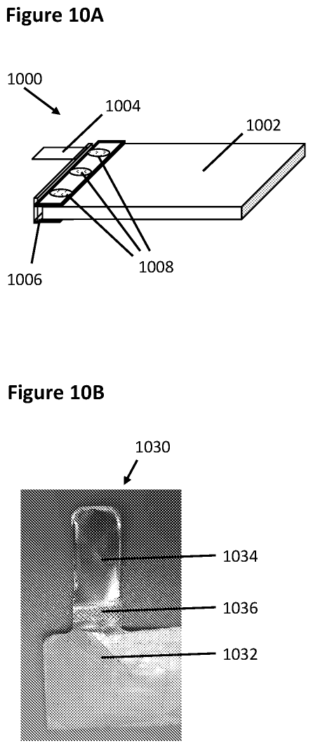

FIG. 8 shows a PVD-copper-coated CNT mat 802 of an electrode 800, in accordance with an embodiment of the present invention. Regarding the PVD approach method 550 (FIG. 5), a photo of a PVD copper coated CNT mat 802 is shown in FIG. 8. The PVD current collector 800 is coated with active material and tabbing may be performed by welding a copper strip directly onto the PVD copper surface (see FIG. 10).

TABLE 2
Experimental Sheet resistance measurements-
CNT-Cu (Perforated)-CNT Sandwich & PVD-CNT

| | | Weight | Weight | Sheet |
|---|---|---|---|---|
| | Thickness* | per area | gain | resistance** |
| Sample | [μm] | [mg/cm²] | [%] | [mΩ/sq.] |
| CNT | 10* | 0.35 | 96%/95% | 1,800-2,200 |
| (pristine) | | | | |
| CNT | 20* | 0.7 | 92%/90% | 700-900 |
| (pristine) | | | | |
| Sandwich | 12 | 3.6 | 60%/49% | 3-5 |
| (2-side) | | | | |
| CNT/Cu/CNT | | | | |
| CNT - 10 μm; | | | | |
| Cu - 8 μm | | | | |
| 60% perforated | | | | |
| Sandwich | 10 | 3.2 | 64%/55% | 3-5 |
| (1-side) | | | | |
| CNT/Cu | | | | |
| CNT - 10 μm; | | | | |
| Cu - 8 μm | | | | |
| 60% perforated | | | | |
| PVD coating | 12-12 | 1.4 | 84%/80% | 20 |
| Cu/CNT/Cu | | | | |
| CNT - 20 μm; | | | | |
| Cu - 0.4 μm | | | | |
| PVD coating | 5-7 | 1.1 | 88%/85% | 20 |
| Cu/CNT/Cu | | | | |
| CNT - 10 μm; | | | | |
| Cu - 0.4 μm | | | | |
| Cu foil | 10 | 8.9 | 0 | 4 |
| | | | | (1.7 Theor.) |
| Cu foil | 8 | 7.1 | 0 | 4 |

*Since CNT is 75%-80% porous the actual thickness depends on the measuring technique.
**Experimental result, including two terminal weld to the substrate. Sheet resistance of 10 micron Copper is 1.7 mohm/sq.

The resistance characteristics for electrodes based on the sandwich 500 (FIG. 5A) and PVD coated mat 550 (FIG. 5B) approaches are compared with values for CNT mat alone and copper foil alone in Table 2.

Table 2 provides sheet resistance of two-point measurement, including the terminal welding (ultrasonic). Since with CNT based mats, termination is a challenge and current invention provides a technique meeting the challenge, it's more practical to include the termination technique and corresponding resistivity.

The various current collectors are listed in the first column including key parameters and construction details. The second column gives “nominal” thickness of the current collector in microns, the third column gives its weight per unit area in mg/sq cm and the fourth gives the weight gain of each current collector compared to a copper foil. The final column gives sheet resistance in mohm/sq for two probe measurements.

It can be seen from Table 2, that 10 micron unperforated copper has the lowest resistivity of 4 mohm/sq (which sets the performance standards for typical lithium-ion power cells) and this only increases to 5 mohm/sq if the foil is 60% perforated.

By contrast, a 10 micron thick CNT mat alone has an impractically high sheet resistance of around 2,000 mohm/sq. However, the sandwich approach in various configuration can equal the copper alone performance at significant weight saving (˜60%) and the PVD approach at 10-20 mohms/sq, is showing promise as to reaching the copper alone performance with similar significant weight savings (and even higher weight savings).

Initially lithium-ion cells built with the novel current collector of either the sandwich or the PVD approach showed marked irreversible capacity loss on formation and regular cycling as compared with standard cells with a plain copper foil current collector. The capacity loss was shown to be caused by electrolyte interaction with the much greater internal surface area of the CNT mat compared with the plain copper foil. Irreversible capacity upon formation is well known with all prior-art LIBs. This problem is solved in the present invention, by limiting electrolyte access to the CNT mat interior (per FIGS. 4A-4D and Table 3). This is performed by treating the CNT mat so as to decrease wetting of the mat by the organic electrolyte that is situated inside the cell. In one embodiment the treatment involved oven heating the CNT mat in air at 450° C. for an hour. Several other techniques to prevent/minimize the wettability of the CNT mat by organic solvent may be implemented.

Another approach is pre-lithiation of the CNT-based electrode thereby causing instantaneous formation of Solid Electrolyte Interphase (SEI) on the Graphite and CNT surface straight upon filling the cell with electrolyte.

A third approach is impregnation of a polymer into the CNT mat void space. Following the impregnation and still before evaporation of the solvent carrying the impregnated polymer, the mat is rolled thereby “Squeezing” the polymer. The rolling/calendaring has a threefold function:
a. thinning the CNT mat;
b. reducing to minimum the weight of the polymer included/impregnated into the CNT pores; and
c. forming a thin polymer “skin” on top of both sides of the CNT mat. The polymer “skin” results at more reliable/easier metallization process of the CNT mat. Also, while forming the skin, there is formed electric isolation between the metallic coating and the CNT fibers. This isolation is beneficial to eliminate electrochemical reaction of the solvent/electrolyte on the CNT fibers.

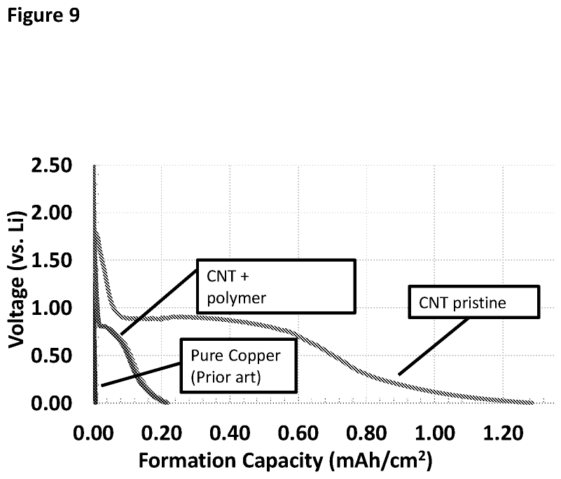

FIG. 9 shows a graph of the formation capacity of various current collectors configuration vs. Li; A CNT-impregnated with polymer current collector in comparison with pristine CNT current collector and pure copper foil current collector (prior art), in accordance with an embodiment of the present invention.

A polymer-impregnated CNT with polymer showed promising results, where the formation capacity of CNT impregnated with polymer provided a formation capacity of around ˜0.2 mAh/cm²). This was a lower formation capacity in comparison with the CNT (˜1.2 mAh/cm²). This indicates that the polymer was indeed impregnated into the bulk of the CNT and covered the CNT surface, which resulted in an electrical insulation between the CNT and the electrolyte and lead to decreased irreversible capacity.

In spite the encouraging results, the values received of the CNT formation capacity were still far from those of copper (˜10 μA/cm²)—the target value.

Following process and instrumentation optimization, much better (smaller) values of formation capacity were achieved such that the CNT-Cu products' values were similar to prior art values of Cu foil—as is shown in table 3.

TABLE 3
Full cells formation capacity with CNT (impregnated with polymer
based anode) and Cu foil based anodes, 2^{nd} generation

| | Polarization cycle | | |
|---|---|---|---|
| | 1^{st} | 2^{nd} | 3^{rd} |
| | Average residual current | | |
| Anode composition | (Avg. μA/cm² @ 10 hr) | | |
| Graphite (treated)/Cu C.C. | 3.1 | 1.7 | 1.2 |
| (prior art) | | | |
| Graphite (treated)/Impregnated | 6 | 3.3 | 2.1 |
| CNT- Cu (PVD) C.C. | | | |

In Table 3, the formation capacity of the full cells that comprised of impregnated CNT based anodes, after 3 polarization cycles is displayed and reaches values that are very close to that of Cu foil—making the impregnated CNT a viable solution as a current collector, which can replace copper foils.

Mechanical properties of polymer impregnated CNT mats compared to metal and polymeric foils are presented below:

TABLE 4
Mechanical properties of pristine CNT, polymer impregnated
CNT and other replacement alternatives

| | Commercial | Thermoplastic | Pristine | Impregnated |
|---|---|---|---|---|
| | Cu | polymeric | CNT | CNT |
| | foil | films | mat | mat |
| Stress | ~350 | 20-165 | 64 | 320 |
| [MPa] | | | | |
| Strain % | ~7 | 10-500 | 15 | 14 |
| 10 μm | 8.9 | 1.2 | 0.4 | 1.8 |
| thickness - | | | | |
| areal density | | | | |
| [mg/cm²] | | | | |

The above results, displayed in table 4, clearly show that the impregnation of polymer into the CNT mat, increases the strength of the CNT while decreasing its strain.

When comparing the mechanical performance of the CNT to its possible replacement alternatives (see table 4) which include: a) Cu foil b) polymeric film, it is seen that the impregnated CNT shows comparable strength as the Cu foil with an increased strain to failure while offering a light weight solution. This indicates that after polymer impregnation, the CNT C.C. is viable to withstand roll-roll battery assembly processes with similar applied forces as on the Cu foil, and still provide increased energy density compared to state-of-the-art (SOTA) lithium ion battery (LIB). In addition, when comparing the impregnated CNT to polymeric film, one can see that even though the polymers offer a light weight solution, they are very weak (i.e. present comparatively low stress to failure) and thus pose handling issues when it comes to roll to roll assembly processes in batteries.

Reference is made to FIG. 10A, which is a simplified diagram of a device 1000 with at least one CNT element 1002 that is ultrasonically welded to a copper foil leg, in accordance with an embodiment of the present invention.

The process steps involved in this tabbing procedure include preparing a copper foil termination hold 1006 according the shape described in FIG. 10A but not limited to a specific design, and cutting a termination leg 1004 out of it. Further the termination hold is intimately placed next to the Cu PVD CNT current collector (CNT element) 1002 and is ultrasonically welded with a weld 1008 along the termination hold. This type of termination (tabbing) presents low electrical contact resistance with the ability to withdraw high currents.

Reference is made to FIG. 10B, is a simplified diagram of a device with at least one CNT element 1030 that is ultrasonically welded to a copper foil leg 1034, in accordance with an embodiment of the present invention.

The process steps involved in this tabbing procedure include cutting a Cu PVD CNT current collector to the shape 1032 (550 seen in FIG. 5B), followed by cutting a termination leg 1034 from a Cu foil and finally ultrasonically welding via a weld 1036 the two parts together.

This type of termination (tabbing) presents higher contact resistance (compared to the device described in FIG. 10A) and thus is more suitable for applications that demand lower currents withdrawal. However this type of termination saves a considerable weight thus retaining higher specific energy of the device.

It should be understood that the CNT-metal products of the present invention may be used for many practical applications. One non-limiting example is for CNT-metal joining techniques such as: brazing, welding, soldering and other connecting methods.

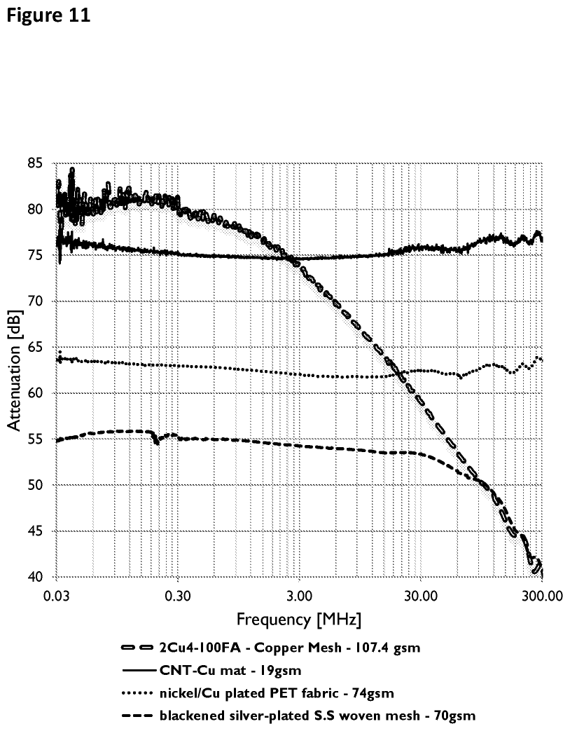

FIG. 11 is a simplified graph presenting the attenuation of EMI shielding materials as a function of electromagnetic frequency. The graph presents the attenuation of an EMI shielding device of the present invention compared with that of standard commercial metalized prior art devices, in accordance with an embodiment of the present invention.

As seen in FIG. 11, the copper coated CNT device of the present invention presents attenuation of 75 dB over the entire frequency range compared to the commercial prior art devices that present lower attenuation over the entire frequency range. In addition, the copper coated CNT device has an areal density of only 19 gr/sqm (gsm) compared to the commercial prior art devices that are heavier with over 70 gr/sqm (gsm). When combing both attributes of performance and weight, the copper coated CNT device provides superior performance compared to prior art devices at a fraction of the weight.

The references cited herein teach many principles that are applicable to the present invention. Therefore the full contents of these publications are incorporated by reference herein where appropriate for teachings of additional or alternative details, features and/or technical background.

It is to be understood that the invention is not limited in its application to the details set forth in the description contained herein or illustrated in the drawings. The invention is capable of other embodiments and of being practiced and carried out in various ways. Those skilled in the art will readily appreciate that various modifications and changes can be applied to the embodiments of the invention as hereinbefore described without departing from its scope, defined in and by the appended claims.

1-28. (canceled)

29. A device comprising at least one carbon nanotube (CNT)-based substrate, the device comprising a first current collector having a resistivity in a range between 1-20 mohm/sq, said first current collector comprising at least one polymer-impregnated carbon nanotube (CNT) substrate of a mean weight per area in a range of 1 to 4 mg/cm² and a tensile strength of more than 200 MPa, and a conducting metallic element attached to said at least one substrate.

30. A device according to claim 1, selected from the group consisting of an electrochemical synthesis cell, an EMI (electromagnetic interference) shielding device or apparatus, a heating element and a lightning strike protection element.

31. An apparatus comprising at least one carbon nanotube (CNT)-based substrate for providing at least one of power and energy, the apparatus comprising:
a. a first current collector having a resistivity in a range between 1-20 mohm/sq, said first current collector comprising:
i. at least one polymer-impregnated carbon nanotube (CNT) mat or substrate of a mean weight per area in a range of 1 to 4 mg/cm² and a tensile strength of more than 200 MPa, and
ii. a high conducting metallic element in electrical connection with a first tab, said high conducting metallic element bound to said at least one carbon nanotube mat;
b. a second current collector comprising a metallic conducting element in electrical connection with a second tab;
c. a separator material separating between said first and second current collectors;
d. an electrolyte solution disposed between said first collector and said second collector; and
e. a housing configured to house the first collector, second collector, separator material and electrolyte solution.

32. An apparatus according to claim 31, wherein said first current collector comprises polymer of a thickness of 1-50 microns, 3-30 microns, or 4-15 microns.

33. An apparatus according to claim 31, wherein said high conducting metallic element comprises copper.

34. An apparatus according to claim 33, wherein said copper is disposed in a perforated foil.

35. An apparatus according to claim 31, wherein said at least one polymer-impregnated carbon nanotube (CNT) mat comprises two polymer-impregnated carbon nanotube (CNT) mats.

36. An apparatus according to claim 35, wherein said high conducting metallic element is sandwiched between said two polymer-impregnated carbon nanotube (CNT) mats.

37. An apparatus according to claim 31, further comprising an active material coated on said at least one mat.

38. An apparatus according to claim 31, wherein said apparatus is a power sources selected from a battery, a capacitor and a fuel cell.

39. An apparatus according to claim 31, wherein said second collector comprises at least one of aluminum, graphite, a silicate, a metal oxide, a phosphate, lithium, an oxide and combinations thereof.

40. An apparatus according to claim 31, configured to provide energy per unit weight of around 50 Wh/kg to 800 Wh/kg.

41. An apparatus according to claim 31, configured to provide power per unit weight of around 200 W/kg to 5 kW/kg.

42. A method for manufacturing an apparatus comprising at least one carbon nanotube (CNT)-based substrate for providing at least one of power and energy, the method comprising:
a. forming a first current collector having a resistivity in a range between 1-20 mohm/sq, comprising:
i. impregnating a carbon nanotube (CNT) mat or substrate with at least one polymer to form at least one polymer-impregnated carbon nanotube (CNT) mat or substrate thereby enhancing a tensile strength of said polymer-impregnated CNT mat or substrate to more than 200 MPa;
ii. binding said at least one polymer-impregnated carbon nanotube (CNT) mat or substrate of a mean weight per area in a range of 1 to 4 mg/cm², with a high conducting metallic element in electrical connection with a first tab; and
iii. coating said at least one polymer-impregnated carbon nanotube (CNT) mat or substrate with an active material.

43. A method according to claim 42, further comprising:
b. preparing a second current collector comprising a metallic conducting element in electrical connection with a second tab and coating said second current collector with an active material:
c. disposing a separator material between said first current collector and said second current collector;
d. introducing said first current collector said second current collector and said separator material into a housing; and
e. adding an electrolyte solution in between said first collector and said second collector thereby forming said apparatus.

44. A method according to claim 42, wherein said forming step is selected from a sandwich approach, electrolytic deposition, electroless deposition and a physical vapor deposition (PVD), CVD, electroplating or electroless plating, magneton sputtering, electron beam coating, seeding, physical deposition, chemical deposition, thermal reduction processing and combinations thereof.

45. A method according to claim 42, wherein said apparatus is a power source selected from a battery, a capacitor and a fuel cell.

46. A method according to claim 45, wherein said battery is a lithium ion battery.

47. A method according to claim 42, wherein said apparatus is a non-energy storage device selected from the group consisting of an electrochemical synthesis cell, an electronic shielding unit, a heating element and a lightning rod.

48. A method according to claim 42, further comprising treating said at least one carbon nanotube (CNT) mat to reduce at least one of a porosity and a wetting thereof or increasing an oleophobicity thereof.
